(19) United States
(12) Patent Application Publication
(10) Pub. No.: US 2017/0117334 A1
(43) Pub. Date: Apr. 27, 2017

(54) ARRAY SUBSTRATE AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Renwei GUO, Beijing (CN); Xue DONG, Beijing (CN); Pengcheng LU, Beijing (CN); Mubing LI, Beijing (CN)

(73) Assignees: BOE TECHNOLOGY GROUP CO., LTD., Beijing (CN); BEIJING BOE OPTOELECTRONICS TECHNOLOGY CO., LTD., Beijing (CN)

(21) Appl. No.: 15/100,175

(22) PCT Filed: Dec. 14, 2015
(86) PCT No.: PCT/CN2015/097262

§ 371 Date: May 27, 2016

(30) Foreign Application Priority Data
Jun. 1, 2015 (CN) 201510293849.7

(51) Int. Cl. H01L 27/32; H01L 27/12

(52) U.S. Cl. CPC H01L 27/3216; H01L 27/124; H01L 27/3276

(57) ABSTRACT

The present disclosure provides an array substrate and a display device. The array substrate includes a plurality of gate lines, a plurality of data lines and a plurality of sub-pixels in pixel areas defined by the gate lines and the data lines. Dimensions of the sub-pixels are identical. Each sub-pixel is in a color different from an adjacent sub-pixel. A quadrate pixel unit is defined by at most two adjacent sub-pixels in each row of sub-pixels, and two adjacent rows of sub-pixels are staggered by ½ sub-pixel in a column direction. The data lines include first data lines. Each of the first data lines is in an interval between a column of sub-pixels and an adjacent column of sub-pixels and is connected with sub-pixels of the two columns.

### CROSS-REFERENCE TO RELATED APPLICATION

This application claims a priority to Chinese Patent Application No. 201510293849.7 filed on Jun. 1, 2015, the disclosures of which are incorporated in their entirety by reference herein.

### TECHNICAL FIELD

The present disclosure relates to the field of communication, and in particular to an array substrate and a display device.

### BACKGROUND

At present, pixels of a display screen are usually arranged in a sequence of R, G, B or a sequence of R, G, B, W, one pixel is formed by three or four sub-pixels, and a physical resolution is the same as an actual resolution for human eyes.

However, along with an improvement of a user experience requirement for the display screen, manufacturers needs to manufacture a display panel with a higher Pixels Per Inch (PPI), which challenges a design of the display panel and a manufacturing process thereof. For example, when manufacturing a sub-pixel with an organic light-emitting diode (OLED), it is very difficult to form an organic resin pattern because a large amount of data lines and gate lines are required. As a result, there may be a bottleneck when manufacturing a display panel with a higher PPI.

Therefore, it is desired to manufacture a display panel with a higher PPI without a large amount of data lines and gate lines in the related art.

### SUMMARY

An object of the present disclosure is to provide a solution for manufacturing a display panel with a relative high PPI without a large amount of data lines and gate lines, so as to make the process less difficult and improve a yield of the product.

To achieve the above object, an array substrate is provided by the present disclosure. The array substrate includes a plurality of gate lines, a plurality of data lines and a plurality of sub-pixels in pixel areas defined by the gate lines and the data lines. Dimensions of the sub-pixels are identical. Each sub-pixel is in a color different from an adjacent sub-pixel. A quadrate pixel unit is defined by at most two adjacent sub-pixels in each row of sub-pixels, and two adjacent rows of sub-pixels are staggered by ½ sub-pixel in a column direction. The data lines include first data lines. Each of the first data lines is in an interval between a column of sub-pixels and an adjacent column of sub-pixels and is connected with sub-pixels of the two columns.

Optionally, the data lines further include a second data line, and the second data line is connected with the sub-pixels of a first column of sub-pixels in sequence and/or the sub-pixels of a last column of sub-pixels in sequence.

Optionally, the first data lines are curved data lines which are curved in an identical direction.

Optionally, the second data line is straight.

Optionally, the gate line corresponding to an odd-numbered row of sub-pixels and the gate line corresponding to an even-numbered row of sub-pixels are paired and arranged in an interval between the odd-numbered row of sub-pixels and the even-numbered row of sub-pixels.

Optionally, the sub-pixels include red (R) sub-pixels, green (G) sub-pixels and blue (B) sub-pixels.

Optionally, the sub-pixels in each odd-numbered row of sub-pixels are repeated in a sequence of R, G, B, and the sub-pixels in each even-numbered row of sub-pixels are repeated in a sequence of B, R, G.

Optionally, the sub-pixels repeated in the sequence of B, R, G in each even-numbered row of sub-pixels are staggered ahead or backwards with the sub-pixels repeated in the sequence of R, G, B in each odd-numbered row of sub-pixels by ½ sub-pixel.

Optionally, the quadrate pixel unit is defined by one sub-pixel, 1.5 sub-pixels or two sub-pixels.

Optionally, the sub-pixels include an X^{th} row of sub-pixels and an (X+1)^{th} row of sub-pixels which is adjacent to the X^{th} row of sub-pixels, wherein X is equal to or greater than 1. The gate line corresponding to the X^{th} row of sub-pixels and the gate line corresponding to the (X+1)^{th} row of sub-pixels are paired and arranged in an interval between the X^{th} row of sub-pixels and the (X+1)^{th} row of sub-pixels.

Optionally, the sub-pixels further include an (X+2)^{th} row of sub-pixels, and only two gate lines including the gate line corresponding to the X^{th} row of sub-pixels and the gate line corresponding to the (X+1)^{th} row of sub-pixels are arranged between the X^{th} row of sub-pixels and the (X+2)^{th} row of sub-pixels.

Optionally, X is an odd number.

Optionally, a display device is further provided by the present disclosure, including the array substrate hereinabove.

As compared with the related art, according to the array substrate and the display device provided by the present disclosure, it is able to process the picture input originally and then redistribute the luminance of the processed picture. By controlling the turn-on positions of the sub-pixels, the redistributed luminance is input to the sub-pixels at the actual physical positions. In addition, the connection mode of the date lines to the sub-pixels and the gate lines is optimized. Accordingly, it is easier to design and manufacture a display panel with a relative high PPI, thereby the process may be less difficult and the yield of the product may be improved.

### BRIEF DESCRIPTION OF THE DRAWINGS

FIG. 1 is a schematic view showing a first connection mode of data lines and gate lines in an array substrate in some embodiments of the present disclosure.

FIG. 2 is a schematic view showing polarities of input signals corresponding to the first connection mode of data lines and gate lines in the array substrate in some embodiments of the present disclosure.

FIG. 3 is a schematic view showing a second connection mode of data lines and gate lines in an array substrate in some embodiments of the present disclosure.

FIG. 4 is a schematic view showing polarities of input signals corresponding to the second connection mode of data lines and gate lines in the array substrate in some embodiments of the present disclosure.

### DETAILED DESCRIPTION

The present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

At present, the Pentile technology has been widely applied in the field of display, the prominent advantage of this technology is that a visual resolution of a display panel is higher than a physical resolution thereof by using a pixel mutually. That is, an image may be displayed clearly by using a relative small amount of pixels without lowering the visual resolution for human eyes. The Pentile technology has been applied in some high-end products of the well-known cell phone manufacturers.

Therefore, a screen resolution for human eyes may be improved by the Pentile technology, such that a viewer may not sense a reduction of the actual resolution caused by a reduction of the physical resolution and then a relative high PPI may be guaranteed.

However, the Pentile technology is defective in terms of a sub-pixel arrangement and a connection mode design of gate lines and data lines, and an image of a relative high resolution may not be displayed by a relative small amount of sub-pixels as a result. For example, when manufacturing a Quarter High Definition (QHD) product of a size smaller than 6 inches (e.g., the size is 2560×14440×3) by A-Si process, it is unable to reduce an amount of the data lines of the panel, and the date lines and the gate lines are connected in a mode of the related art, so there may be a bottleneck of A-Si design and manufacture in the LTPS and OLED process.

In view of this, an array substrate is provided in some embodiments of the present disclosure, including a plurality of gate lines, a plurality of data lines and a plurality of sub-pixels arranged in pixel areas defined by the gate lines and the data lines. Dimensions of the sub-pixels are identical. Each sub-pixel is in a color different from an adjacent sub-pixel. A quadrate pixel unit is defined by at most two adjacent sub-pixels in each row of sub-pixels, and two adjacent rows of sub-pixels are staggered by ½ sub-pixel in a column direction. The data lines include first data lines each be arranged in an interval between a column of sub-pixels and an adjacent column of sub-pixels and is connected with sub-pixels of the two columns.

In some embodiments of the present disclosure, a half of sub-pixel is a base unit, and each quadrate pixel unit is designed to include one sub-pixel, 1.5 sub-pixels or two sub-pixels, and two adjacent rows of sub-pixels are staggered by ½ sub-pixel, so as to make a shape and a length of each data line regular without increasing a process difficulty when arranging the data lines.

In addition, each data line is configured to input data to two adjacent columns of sub-pixel simultaneously, so an amount of the data lines is halved, thereby to facilitate the design and process thereof.

A virtual display is realized by the array substrate with the pixel arrangement hereinabove in conjunction with a virtual calculation technology (i.e., inputting information corresponding to actual physical locations, redistributing luminance for the input information and outputting the same to the physical locations). In other words, there is a plurality of B sub-pixels adjacent to the current R sub-pixel; when it is to display in blue, a red luminance value of the R sub-pixel is decreased to minimum or even 0, and a blue luminance value to be displayed is distributed in different proportions to the adjacent B sub-pixels. At this point, although the R sub-pixel does not display in blue actually, finally it seems like that the R sub-pixel displays in blue because of the B sub-pixels surrounding the R sub-pixel.

The way of displaying image information will be described hereinafter with embodiments.

For example, when a white image is to be displayed, three sub-pixels adjacent to each another and arranged in a triangle at a position where a pixel unit which is to display the white image is, may be turned on, so as to display the white image. As compared with the technology in the related art where three adjacent columns of R, G, B sub-pixels need to be turned on when a white image is displayed, the sub-pixels may be turned on selectively without reducing sizes of the pixels in some embodiments of the present disclosure, so as to display the same information with a relative small amount of pixels, thereby improving an output resolution of the displayed image.

For another example, when a red vertical line is to be displayed, a column of red sub-pixels at one side of the red vertical line may be turned on, or the red sub-pixels at both sides of the red vertical line may be turned on, so as to perform a phong shading on the displayed red vertical line, thereby to make the displayed red vertical line clearer and then improve the display effect. In addition, when two red vertical lines very close to each other are to be displayed, a column of red sub-pixels between the two red vertical lines may be turned on, so as to render the displayed red vertical lines, thereby to make the two red vertical lines more directional and then improve the visual resolution.

In some embodiments of the present disclosure, the data lines may further include a second data line configured to connect the sub-pixels of a first column of sub-pixels in sequence and/or the sub-pixels of a last column of sub-pixels in sequence. In other words, the data lines may be arranged as the first data lines, where each first data line is arranged between two adjacent columns of sub-pixels so as to be connected with sub-pixels of the two columns, thereby to halve the amount of the data lines.

However, it should be noted that, the data line on the very edge connects only one column of sub-pixels in sequence, so it may be arranged as the second data line.

In some embodiments of the present disclosure, the first data lines may be curved data lines which are curved in an identical direction. The second data line may be a straight data line.

In some embodiments of the present disclosure, the connection mode of the gate lines is also different from the related art. To be specific, the gate line corresponding to an odd-numbered row of sub-pixels and the gate line corresponding to an even-numbered row of sub-pixels are paired and arranged in an interval between the odd-numbered row of sub-pixels and the even-numbered row of sub-pixels.

In other words, a gate line connecting the sub-pixels of the first row of sub-pixels in sequence is parallel to a gate line connecting the sub-pixels of the second row of sub-pixels in sequence, and both the two gate lines are arranged between the first and the second rows of sub-pixels. A gate line connecting the sub-pixels of the third row of sub-pixels in sequence is parallel to a gate line connecting the sub-pixels of the fourth row of sub-pixels in sequence, and both the two gate lines are arranged between the third and the fourth rows of sub-pixels. The rest can be done in the same manner.

Based on the description hereinabove, in some embodiments of the present disclosure, there are two connection modes of the data lines and the gate lines, where the difference between the two modes lies in the connection mode of the data lines.

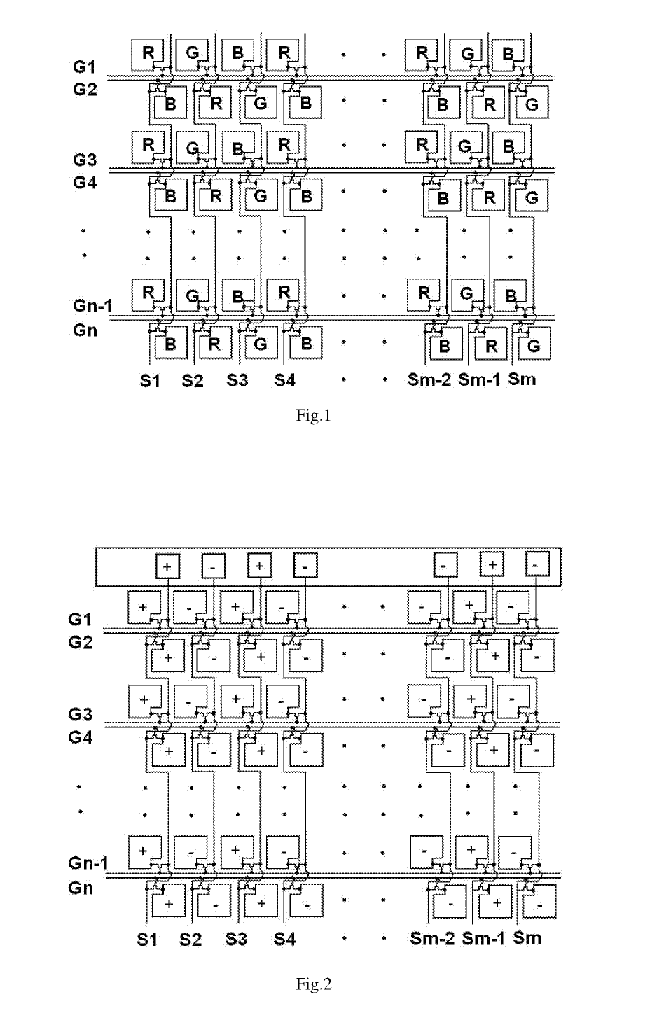

In the first connection mode, the data lines are all curved data lines curved in an identical direction. FIG. 1 is a schematic view showing the first connection mode of data lines and gate lines in an array substrate in some embodiments of the present disclosure, which may be made a reference to facilitate the understanding. As shown in FIG. 1, G1 to Gn represent the gate lines arranged horizontally, and S1 to Sm+1 represent the data lines arranged vertically. The data lines are all curved data lines which are all curved to left. From the first row of the gate line, the gate lines powering each two adjacent rows of sub-pixels are paired and arranged in an interval between the two adjacent rows of sub-pixels.

In some embodiments of the present disclosure where a quadrate pixel unit is defined by one R sub-pixel, one G sub-pixel and one B sub-pixel, n may be 2560 and m may be 2160. In some embodiments of the present disclosure where a quadrate pixel unit is defined by 1.5 R sub-pixels, 1.5 G sub-pixels and 1.5 B sub-pixels, n may be 3840 and m may be 4320. In some embodiments of the present disclosure where a quadrate pixel unit is defined by two R sub-pixels, two G sub-pixels and two B sub-pixels, n may be 7680 and m may be 5760.

Chinese application No. 201510149457.3 may be made a reference for a structure of the quadrate pixel unit, which is incorporated herein by reference in its entirety.

FIG. 2 is a schematic view showing polarities of input signals corresponding to the first connection mode of data lines and gate lines in an array substrate in some embodiments of the present disclosure. As shown in FIG. 2, polarities of S1 and S2 are “+” and “−” respectively.

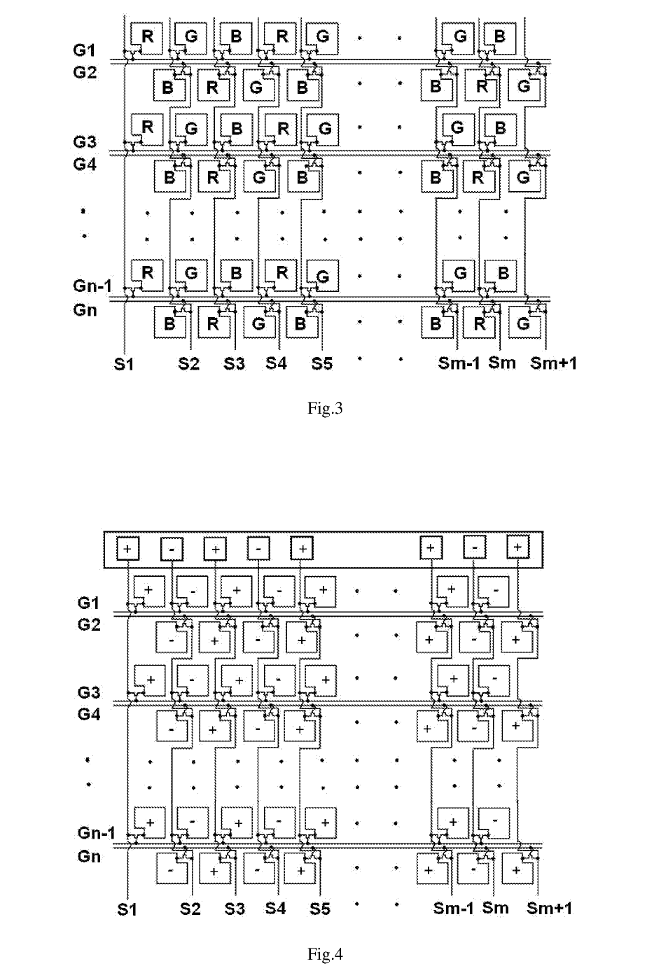

In the second connection mode, the sub-pixels of the first column and/or the last column of sub-pixels are connected in sequence by a straight data line, and the sub-pixels of the rest columns of sub-pixels are connected in sequence by curved data lines which are curved in an identical direction. FIG. 3 is a schematic view showing a second connection mode of data lines and gate lines in an array substrate in some embodiments of the present disclosure, which may be made a reference to facilitate the understanding. As shown in FIG. 3, G1 to Gn represent the gate lines arranged horizontally, and S1 to Sm represent the data lines arranged vertically. S1 is a straight data line, S2 to Sm are curved data lines which are all curved to right. From the first row of the gate line, the gate lines powering each two adjacent rows of sub-pixels are paired and arranged in an interval between the two adjacent rows of sub-pixels.

Optionally, in some embodiments of the present disclosure, the sub-pixels include R sub-pixels, G sub-pixels and B sub-pixels. The sub-pixels in each odd-numbered row of sub-pixels are repeated in a sequence of R, G, B, and the sub-pixels in each even-numbered row of sub-pixels are repeated in a sequence of B, R, G.

The sub-pixels repeated in the sequence of B, R, G in each even-numbered row of sub-pixels are staggered ahead or backwards with the sub-pixels repeated in the sequence of R, G, B in each odd-numbered row of sub-pixels by ½ sub-pixel.

FIG. 4 is a schematic view showing polarities of input signals corresponding to the second connection mode of data lines and gate lines in an array substrate in some embodiments of the present disclosure. As shown in FIG. 4, polarities of S1 and S2 are “+” and “−” respectively.

According to the embodiments hereinabove, the amount of the data lines may be reduced, and the connection mode of data lines and gate lines are redesigned, thereby to overcome the bottleneck in the A-Si design.

In addition, the embodiments hereinabove may also applicable to a low temperature poly-silicon (LTPS) process, an OLED process and so on, which may be conductive to manufacture a product with high PPI.

On this basis, it is further practicable to drive an entire display panel including the array substrate hereinabove with only one integrated circuit (IC) chip. According to such integrative IC design, it is able to reduce the amount of the data lines and a power consumption of the IC of the panel, thereby the IC may drive the display panel with a low power consumption.

Based on the same inventive concept, a display device is further provided in some embodiments of the present disclosure, including the array substrate hereinabove. The display device may be applied to a product or a component with display function such as cell phone, tablet PC, television, display, laptop computer, digital photo frame and navigator. A working principle of the display device is similar to that of the array substrate, so the embodiments of the array substrate hereinabove may be made a reference to the display device, and the description thereof is omitted herein.

According to the embodiments hereinabove, it is able to process the picture input originally and then redistribute the luminance of the processed picture. By controlling the turn-on positions of the sub-pixels, the redistributed luminance is input to the sub-pixels at the actual physical positions. In addition, the connection mode of the date lines to the sub-pixels and the gate lines is optimized. Accordingly, it is easier to design and manufacture a display panel with a relative high PPI, thereby the process may be less difficult and the yield of the product may be improved.

The above are merely the optional embodiments of the present disclosure. A person skilled in the art may make further modifications and improvements without departing from the principle of the present disclosure, and these modifications and improvements shall also fall within the scope of the present disclosure.

1. An array substrate, comprising a plurality of gate lines, a plurality of data lines and a plurality of sub-pixels in pixel areas defined by the gate lines and the data lines;
wherein dimensions of the sub-pixels are identical;
wherein each sub-pixel is in a color different from an adjacent sub-pixel, a quadrate pixel unit is defined by at most two adjacent sub-pixels in each row of sub-pixels, and two adjacent rows of sub-pixels are staggered by ½ sub-pixel in a column direction;
wherein the data lines comprise first data lines, and each of the first data lines is in an interval between a column of sub-pixels and an adjacent column of sub-pixels and is connected with sub-pixels of the two columns.

2. The array substrate according to claim 1, wherein the data lines further comprise a second data line, and the second date line is connected with the sub-pixels of a first column of sub-pixels in sequence and/or the sub-pixels of a last column of sub-pixels in sequence.

3. The array substrate according to claim 2, wherein the first data lines are curved data lines which are curved in an identical direction.

4. The array substrate according to claim 2, wherein the second data line is straight.

5. The array substrate according to claim 2, wherein the gate line corresponding to an odd-numbered row of sub-pixels and the gate line corresponding to an even-numbered row of sub-pixels are paired and arranged in an interval between the odd-numbered row of sub-pixels and the even-numbered row of sub-pixels.

6. The array substrate according to claim 1, wherein the sub-pixels comprise red (R) sub-pixels, green (G) sub-pixels and blue (B) sub-pixels.

7. The array substrate according to claim 6, wherein the sub-pixels in each odd-numbered row of sub-pixels are repeated in a sequence of R, G, B, and the sub-pixels in each even-numbered row of sub-pixels are repeated in a sequence of B, R, G.

8. The array substrate according to claim 6, wherein the sub-pixels repeated in the sequence of B, R, G in each even-numbered row of sub-pixels are staggered ahead or backwards with the sub-pixels repeated in the sequence of R, G, B in each odd-numbered row of sub-pixels by ½ sub-pixel.

9. The array substrate according to claim 1, wherein the quadrate pixel unit is defined by one sub-pixel, 1.5 sub-pixels or two sub-pixels.

10. The array substrate according to claim 1, wherein the sub-pixels comprise an X^{th} row of sub-pixels and an (X+1)^{th} row of sub-pixels which is adjacent to the X^{th} row of sub-pixels, wherein X is equal to or greater than 1;
the gate line corresponding to the X^{th} row of sub-pixels and the gate line corresponding to the (X+1)^{th} row of sub-pixels are paired and arranged in an interval between the X^{th} row of sub-pixels and the (X+1)^{th} row of sub-pixels.

11. The array substrate according to claim 10, wherein the sub-pixels further comprise an (X+2)^{th} row of sub-pixels; only two gate lines including the gate line corresponding to the X^{th} row of sub-pixels and the gate line corresponding to the (X+1)^{th} row of sub-pixels are between the X^{th} row of sub-pixels and the (X+2)^{th} row of sub-pixels.

12. The array substrate according to claim 10, where X is an odd number.

13. A display device, comprising the array substrate according to claim 1.

14. The array substrate according to claim 3, wherein the sub-pixels comprise red (R) sub-pixels, green (G) sub-pixels and blue (B) sub-pixels.

15. The array substrate according to claim 5, wherein the sub-pixels comprise red (R) sub-pixels, green (G) sub-pixels and blue (B) sub-pixels.

16. The array substrate according to claim 14, wherein the sub-pixels in each odd-numbered row of sub-pixels are repeated in a sequence of R, G, B, and the sub-pixels in each even-numbered row of sub-pixels are repeated in a sequence of B, R, G.

17. The array substrate according to claim 14, wherein the sub-pixels repeated in the sequence of B, R, G in each even-numbered row of sub-pixels are staggered ahead or backwards with the sub-pixels repeated in the sequence of R, G, B in each odd-numbered row of sub-pixels by ½ sub-pixel.

18. The array substrate according to claim 15, wherein the sub-pixels in each odd-numbered row of sub-pixels are repeated in a sequence of R, G, B, and the sub-pixels in each even-numbered row of sub-pixels are repeated in a sequence of B, R, G.

19. The array substrate according to claim 15, wherein the sub-pixels repeated in the sequence of B, R, G in each even-numbered row of sub-pixels are staggered ahead or backwards with the sub-pixels repeated in the sequence of R, G, B in each odd-numbered row of sub-pixels by ½ sub-pixel.

20. The array substrate according to claim 11, where X is an odd number.
